(19) United States
(12) Patent Application Publication
(10) Pub. No.: US 2025/0239547 A1
(43) Pub. Date: Jul. 24, 2025

(54) SEMICONDUCTOR DEVICE STRUCTURE HAVING HYBRID BOND STRUCTURE WITH AIR GAP AND METHOD OF MANUFACTURING THE SAME

(71) Applicant: NANYA TECHNOLOGY CORPORATION, NEW TAIPEI CITY (TW)

(72) Inventor: HSIH-YANG CHIU, TAOYUAN CITY (TW)

(21) Appl. No.: 18/797,631

(22) Filed: Aug. 8, 2024

Related U.S. Application Data
(62) Division of application No. 18/421,049, filed on Jan. 24, 2024.

(51) Int. Cl. H01L 23/00

(52) U.S. Cl. CPC H01L 24/03; H01L 24/05; H01L 24/06; H01L 24/08; H01L 24/80; H01L 2224/03001; H01L 2224/0345; H01L 2224/03452; H01L 2224/03616; H01L 2224/03845; H01L 2224/05556; H01L 2224/05624; H01L 2224/05647; H01L 2224/05666; H01L 2224/0568; H01L 2224/05681; H01L 2224/05684; H01L 2224/05686; H01L 2224/0603; H01L 2224/08121; H01L 2224/08145; H01L 2224/80365; H01L 2224/80379; H01L 2224/80896; H01L 2924/04941; H01L 2924/04953; H01L 2924/05042; H01L 2924/0544; H01L 2924/059

(57) ABSTRACT

A semiconductor device structure and method for manufacturing the same are provided. The semiconductor device structure includes a first substrate, a second substrate, and a hybrid bond structure. The second substrate is bonded to the first substrate by the hybrid bond structure. The hybrid bond structure includes a dielectric structure, a conductive structure. The dielectric structure defines an air gap therein.

### CROSS-REFERENCE TO RELATED APPLICATION

This application is a divisional application of U.S. Non-Provisional application Ser. No. 18/421,049 filed Jan. 24, 2024, which is incorporated herein by reference in its entirety.

### TECHNICAL FIELD

The present disclosure relates to a semiconductor device structure and method of manufacturing the same, and in particularly to a semiconductor layer including a hybrid bond structure with an air gap.

### DISCUSSION OF THE BACKGROUND

With the rapid growth of the electronics industry, the development of integrated circuits (ICs) has achieved high performance and miniaturization. Technological advances in IC materials and design have produced generations of ICs where each generation has smaller and more complex circuits than the previous generation.

A Dynamic Random Access Memory (DRAM) device is a type of random access memory that stores each bit of data in a separate capacitor within an integrated circuit. Typically, a DRAM is arranged in a square array of one capacitor and transistor per cell. A vertical transistor has been developed for the 4F² DRAM cell, where F stands for the photolithographic minimum feature width or critical dimension (CD). However, recently, DRAM manufacturers face the tremendous challenge of shrinking the memory cell area as the word line spacing continues to shrink.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device structure. The semiconductor device structure includes a first substrate, a second substrate, and a hybrid bond structure. The second substrate is bonded to the first substrate by the hybrid bond structure. The hybrid bond structure includes a dielectric structure, a conductive structure. The dielectric structure defines an air gap therein.

Another aspect of the present disclosure provides a semiconductor device structure. The semiconductor device structure includes a first substrate, a passivation layer, a conductive line, a dielectric structure, a first conductive layer, a second conductive layer, and an air gap. The passivation layer is disposed over the first substrate. The conductive line is disposed within the passivation layer. The dielectric structure is disposed over the passivation layer. The first conductive layer is electrically connected to the conductive line. The second conductive layer is disposed over the first conductive layer and electrically connected to the conductive line through the first conductive layer. The air gap is disposed within the dielectric structure. The air gap laterally overlaps the first conductive layer.

Another aspect of the present disclosure provides a method for manufacturing a semiconductor device structure. The method includes: providing a first substrate; forming a first dielectric layer over the first substrate, wherein the first dielectric layer defines a first opening and a second opening; forming a first conductive layer within the first opening; providing a second substrate, wherein a second dielectric layer is formed on the second substrate, a second conductive layer penetrates the second dielectric layer, and the second dielectric layer defines a third opening; and bonding the first dielectric layer to the second dielectric layer and bonding the first conductive layer and the second conductive layer to define a hybrid bond structure with an air gap formed by the second opening and the third opening.

The embodiments of the present disclosure provide a semiconductor device structure and method of manufacturing the same. The semiconductor device structure may include a first substrate and a second substrate bonded to the first substrate through a hybrid bond technique. In this embodiment, the hybrid bond structure includes an air gap so that the parasitic capacitance between abutting conductive structures within the hybrid bond structure can be reduced.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a cross-sectional view of a semiconductor device structure, in accordance with some embodiments of the present disclosure.

FIG. 2 is a cross-sectional view of a semiconductor device structure, in accordance with some embodiments of the present disclosure.

FIG. 3 is a cross-sectional view of a semiconductor device structure, in accordance with some embodiments of the present disclosure.

FIG. 4 illustrates one or more stages of an exemplary method for manufacturing a semiconductor device structure according to some embodiments of the present disclosure.

FIG. 5 illustrates one or more stages of an exemplary method for manufacturing a semiconductor device structure according to some embodiments of the present disclosure.

FIG. 6 illustrates one or more stages of an exemplary method for manufacturing a semiconductor device structure according to some embodiments of the present disclosure.

FIG. 7 illustrates one or more stages of an exemplary method for manufacturing a semiconductor device structure according to some embodiments of the present disclosure.

FIG. 8 illustrates one or more stages of an exemplary method for manufacturing a semiconductor device structure according to some embodiments of the present disclosure.

FIG. 9 illustrates one or more stages of an exemplary method for manufacturing a semiconductor device structure according to some embodiments of the present disclosure.

FIG. 10 illustrates one or more stages of an exemplary method for manufacturing a semiconductor device structure according to some embodiments of the present disclosure.

FIG. 11 illustrates one or more stages of an exemplary method for manufacturing a semiconductor device structure according to some embodiments of the present disclosure.

FIG. 12 illustrates one or more stages of an exemplary method for manufacturing a semiconductor device structure according to some embodiments of the present disclosure.

FIG. 13 illustrates one or more stages of an exemplary method for manufacturing a semiconductor device structure according to some embodiments of the present disclosure.

FIG. 14 illustrates one or more stages of an exemplary method for manufacturing a semiconductor device structure according to some embodiments of the present disclosure.

FIG. 15 illustrates one or more stages of an exemplary method for manufacturing a semiconductor device structure according to some embodiments of the present disclosure.

FIG. 16 illustrates one or more stages of an exemplary method for manufacturing a semiconductor device structure according to some embodiments of the present disclosure.

FIG. 17 is a flowchart illustrating a method of manufacturing a semiconductor device structure, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that when an element is referred to as being “connected to” or “coupled to” another element, the initial element may be directly connected to, or coupled to, another element, or to other intervening elements.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

It should be noted that the term “about” modifying the quantity of an ingredient, component, or reactant of the present disclosure employed refers to variation in the numerical quantity that may occur, for example, through typical measuring and liquid handling procedures used for making concentrates or solutions. Furthermore, variation may occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10, 9, 8, 7, 6, 5, 4, 3, 2, or 1% of the reported numerical value.

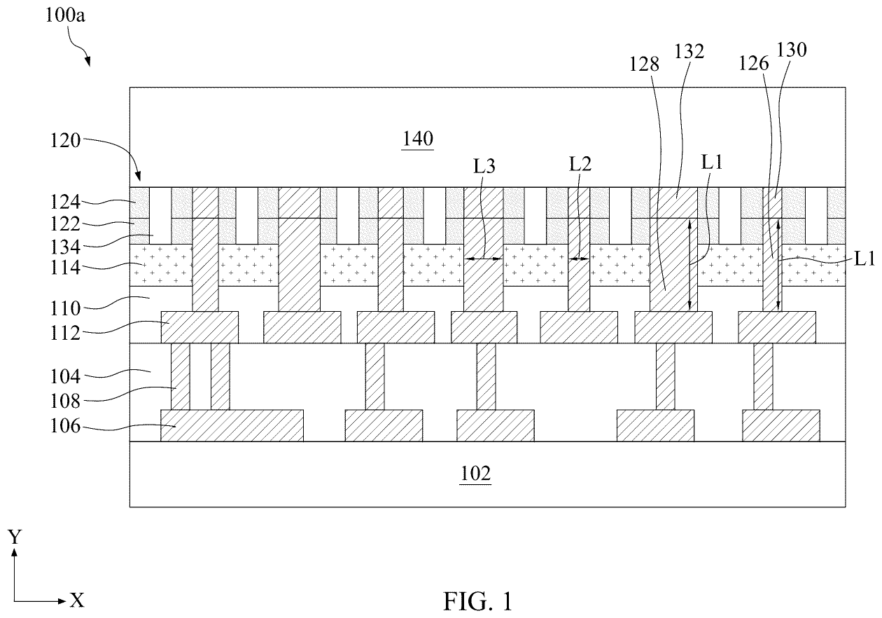

FIG. 1 is a cross-sectional view of a semiconductor device structure 100a, in accordance with some embodiments of the present disclosure.

In some embodiments, the 100a may include a first substrate 102, a hybrid bond structure 120, and a second substrate 140. In some embodiments, the first substrate 102 may be bonded or attached to the second substrate 140 by the hybrid bond structure 120.

The first substrate 102 may include a semiconductor carrier (or wafer) and integrated circuit (IC) devices formed within and/or on the semiconductor carrier. The semiconductor carrier may include a bulk semiconductor, a semiconductor-on-insulator (SOI) substrate, or the like. The semiconductor carrier may include an elementary semiconductor including silicon or germanium in a single crystal form, a polycrystalline form, or an amorphous form, a compound semiconductor material including at least one of silicon carbide, gallium arsenide, gallium phosphide, indium phosphide, indium arsenide, and indium antimonide, an alloy semiconductor material including at least one of SiGe, GaAsP, AlInAs, AlGaAs, GaInAs, GaInP, and GaInAsP, any other suitable material, or a combination thereof. In some embodiments, the alloy semiconductor substrate may include a SiGe alloy with a gradient Ge feature in which the Si and Ge composition changes from one ratio at one location to another ratio with location of the feature. In another embodiment, the SiGe alloy is formed over a silicon substrate. In some embodiments, a SiGe alloy may be mechanically strained by another material in contact with the SiGe alloy. In some embodiments, the semiconductor carrier may have a multilayer structure, or the semiconductor carrier may include a multilayer compound semiconductor structure. It should be noted that some doped regions, isolation structures, and/or other features may be formed within the semiconductor carrier.

In some embodiments, the IC device may include active devices such as transistors and/or passive devices such as resistors, capacitors, inductors, or a combination thereof. For example, the IC device may include a memory (e.g., DRAM), an application-specific IC (ASIC), a memory integrated circuit, a radio frequency integrated circuit (RFIC), a central processing unit (CPU), a microprocessor unit (MPU), a graphics processing unit (GPU), a microcontroller unit (MCU), a field-programmable gate array (FPGA), a power management IC (PMIC), or other type of IC.

In some embodiments, the semiconductor device structure 100a may include an interlayer dielectric 104. The interlayer dielectric 104 may be disposed on the first substrate 102. The interlayer dielectric 104 may include a multi-layered structure. The interlayer dielectric 104 may include, for example, silicon oxide (SiOₓ), silicon nitride (SiₓN_{y}), silicon oxynitride (SiON), phosphosilicate glass (PSG), borophosphosilicate glass (BPSG), a low-k dielectric material (k<4), or other suitable materials. In some embodiments, the interlayer dielectric 104 may also be referred to as an interlayer dielectric (ILD).

In some embodiments, the semiconductor device structure 100a may include a conductive line 106. The conductive line 106 may be disposed on the first substrate 102. The conductive line 106 may be electrically connected to the IC device(s) within the first substrate 102. The conductive line 106 may be embedded within the interlayer dielectric 104. The interlayer dielectric 104 may include copper (Cu), tungsten (W), aluminum (Al), tantalum (Ta), molybdenum (Mo), tantalum nitride (TaN), titanium, titanium nitride (TiN), the like, and/or a combination thereof. In some embodiments, the interlayer dielectric 104 may also be referred to as the “M (N)” layer, wherein the N is equal to a positive integer, such as 1, 2, or the like.

In some embodiments, the semiconductor device structure 100a may include a conductive via 108. The conductive via 108 may be disposed on and electrically connected to the conductive line 106. The conductive via 108 may be embedded within the interlayer dielectric 104. The conductive via 108 may include copper, tungsten, aluminum, tantalum, molybdenum, tantalum nitride, titanium, titanium nitride, the like, and/or a combination thereof.

In some embodiments, the semiconductor device structure 100a may include an interlayer dielectric 110. In some embodiments, the interlayer dielectric 110 may be disposed on the interlayer dielectric 104. The interlayer dielectric 110 may include a multi-layered structure. The interlayer dielectric 110 may include, for example, silicon oxide, silicon nitride, silicon oxynitride, phosphosilicate glass, borophosphosilicate glass, a low-k dielectric material, or other suitable materials.

In some embodiments, the semiconductor device structure 100a may include a conductive line 112. The conductive line 112 may be disposed on and electrically connected to the conductive via 108. The conductive line 112 may be embedded within the interlayer dielectric 110. The conductive line 112 may include copper, tungsten, aluminum, tantalum, molybdenum, tantalum nitride, titanium, titanium nitride, the like, and/or a combination thereof. In some embodiments, the conductive line 112 may also be referred to as the “M (N+1)” layer. For example, the conductive line 106 is the M1 layer, and the conductive line 112 is the M2 layer.

In some embodiments, the semiconductor device structure 100a may include a passivation layer 114. In some embodiments, the interlayer dielectric 110 may be disposed on the passivation layer 114. The passivation layer 114 may include, for example, silicon oxide, silicon nitride, silicon oxynitride, phosphosilicate glass, borophosphosilicate glass, a low-k dielectric material, or other suitable materials. In some embodiments, the passivation layer 114 may be omitted.

In some embodiments, the hybrid bond structure 120 may be disposed on the passivation layer 114. In some embodiments, the hybrid bond structure 120 may include a bonding interface formed by a hybrid-bonding technique, which involves at least two materials bonded. In some embodiments, the hybrid bond structure 120 may include a first dielectric layer 122, a second dielectric layer 124, a conductive layer 126, a conductive layer 128, a conductive layer 130, a conductive layer 132, and an air gap 134.

In some embodiments, the first dielectric layer 122 may be disposed on the passivation layer 114. In some embodiments, the first dielectric layer 122 may include for example, silicon carbonitride, silicon carbide, silicon oxide, silicon nitride, silicon oxynitride, or other suitable materials. In some embodiments, the material of the first dielectric layer 122 may be different from that of the passivation layer 114. For example, the first dielectric layer 122 may include or be made of silicon carbonitride, and the passivation layer 114 may include or be made of silicon oxide. In some embodiments, the material of the first dielectric layer 122 may be different from that of the passivation layer 114. In the embodiments where the passivation layer 114 is not formed, the first dielectric layer 122 may be directly in contact with the interlayer dielectric 110.

In some embodiments, the second dielectric layer 124 may be disposed on the first dielectric layer 122. In some embodiments, the second dielectric layer 124 may be bonded to the first dielectric layer 122. In some embodiments, no interface or nonobvious interface is between the first dielectric layer 122 and the second dielectric layer 124. In some embodiments, the second dielectric layer 124 may include for example, silicon carbonitride, silicon carbide, silicon oxide, silicon nitride, silicon oxynitride, or other suitable materials. In some embodiments, the material of the second dielectric layer 124 may be the same as or similar to the first dielectric layer 122. In some embodiments, the first dielectric layer 122 and the second dielectric layer 124 may be collaboratively referred to as a dielectric structure.

In some embodiments, the conductive layer 126 may be disposed on the passivation layer 114. In some embodiments, the conductive layer 126 may penetrate the first dielectric layer 122. In some embodiments, the conductive layer 126 may penetrate the passivation layer 114. In some embodiments, the conductive layer 126 may penetrate the interlayer dielectric 110. In some embodiments, the conductive layer 126 may be electrically connected to the conductive line 112. In some embodiments, the first dielectric layer 122 may include for example, copper, tungsten, aluminum, tantalum, molybdenum, tantalum nitride, titanium, titanium nitride, the like, and/or a combination thereof.

In some embodiments, the conductive layer 128 may be disposed on the passivation layer 114. In some embodiments, the conductive layer 128 may penetrate the first dielectric layer 122. In some embodiments, the conductive layer 128 may penetrate the passivation layer 114. In some embodiments, the conductive layer 128 may penetrate the interlayer dielectric 110. In some embodiments, the conductive layer 128 may be electrically connected to the conductive line 112. In some embodiments, the conductive layer 128 may include for example, copper, tungsten, aluminum, tantalum, molybdenum, tantalum nitride, titanium, titanium nitride, the like, and/or a combination thereof. The conductive layer 128 may be located at an elevation the same as that of the conductive layer 126 with respect to the first substrate 102. In some embodiments, the conductive layer 126 and conductive layer 128 may have different dimensions. The conductive layer 126 may have a length (or width or diameter) L1 along the X direction. The conductive layer 126 may have a length (or width or diameter) L2 along the Y direction. The conductive layer 128 may have the length L1 along the X direction. The conductive layer 128 may have a length (or width or diameter) L3 along the Y direction. In some embodiments, the length L1 may be greater than the length L2. In some embodiments, the length L1 may be greater than the length L3. In some embodiments, the length L3 may be greater than the length L2.

In some embodiments, the conductive layer 130 may be disposed on the conductive layer 126. In some embodiments, the conductive layer 130 may penetrate the second dielectric layer 124. In some embodiments, the conductive layer 130 may be electrically connected to the conductive layer 126. In some embodiments, the first dielectric layer 122 may include for example, copper, tungsten, aluminum, tantalum, molybdenum, tantalum nitride, titanium, titanium nitride, the like, and/or a combination thereof.

In some embodiments, the conductive layer 132 may be disposed on the conductive layer 128. In some embodiments, the conductive layer 132 may penetrate the second dielectric layer 124. In some embodiments, the conductive layer 132 may be electrically connected to the conductive layer 128. In some embodiments, the conductive layer 132 may include for example, copper, tungsten, aluminum, tantalum, molybdenum, tantalum nitride, titanium, titanium nitride, the like, and/or a combination thereof.

In some embodiments, the conductive layer 126 and conductive layer 130 may be collaboratively referred to as a first conductive structure, and each of the conductive layer 126 and conductive layer 130 may be regarded as a segment of the first conductive structure. In some embodiments, the conductive layer 128 and conductive layer 132 may be collaboratively referred to as a second conductive structure, and each of the conductive layer 128 and conductive layer 132 may be regarded as a segment of the second conductive structure.

In some embodiments, the air gap 134 may be embedded within the first dielectric layer 122 and the second dielectric layer 124. In some embodiments, the air gap 134 may be defined by the second substrate 140, the first dielectric layer 122, the second dielectric layer 124, and the passivation layer 114. In some embodiments, the air gap 134 may be spaced apart from the conductive layers 126, 128, 130, and 132. In some embodiments, the air gap 134 may be configured to reduce a parasitic capacitance between abutting conductive structures. The first conductive structure (e.g., the conductive layer 126 and conductive layer 130) may define a pitch P1. The second conductive structure (e.g., the conductive layer 128 and conductive layer 132) may define a pitch P2. The air gap 134 may define a pitch P3. In some embodiments, the pitch P3 may be less than the pitch P1. In some embodiments, the pitch P3 may be less than the pitch P2.

In some embodiments, the second substrate 140 may be disposed on the hybrid bond structure 120. The second substrate 140 may include a semiconductor carrier (or wafer) and IC devices formed within and/or on the semiconductor carrier. The semiconductor carrier may include a bulk semiconductor, a semiconductor-on-insulator substrate, or the like. The semiconductor carrier may include an elementary semiconductor including silicon or germanium in a single crystal form, a polycrystalline form, or an amorphous form, a compound semiconductor material including at least one of silicon carbide, gallium arsenide, gallium phosphide, indium phosphide, indium arsenide, and indium antimonide, an alloy semiconductor material including at least one of SiGe, GaAsP, AlInAs, AlGaAs, GaInAs, GaInP, and GaInAsP, any other suitable material, or a combination thereof. In some embodiments, the alloy semiconductor substrate may include a SiGe alloy with a gradient Ge feature in which the Si and Ge composition changes from one ratio at one location to another ratio with location of the feature. In another embodiment, the SiGe alloy is formed over a silicon substrate. In some embodiments, a SiGe alloy may be mechanically strained by another material in contact with the SiGe alloy. In some embodiments, the semiconductor carrier may have a multilayer structure, or the semiconductor carrier may include a multilayer compound semiconductor structure. It should be noted that some doped regions, isolation structures, and/or other features may be formed within the semiconductor carrier.

In some embodiments, the IC device may include active devices such as transistors and/or passive devices such as resistors, capacitors, inductors, or a combination thereof. For example, the IC device may include a memory (e.g., DRAM), an application-specific IC (ASIC), a memory integrated circuit, a radio frequency integrated circuit (RFIC), a central processing unit (CPU), a microprocessor unit (MPU), a graphics processing unit (GPU), a microcontroller unit (MCU), a field-programmable gate array (FPGA), a power management IC (PMIC), or other type of IC.

The second substrate 140 may further include electrical interconnections (not shown) between the IC device(s) and the hybrid bond structure 120.

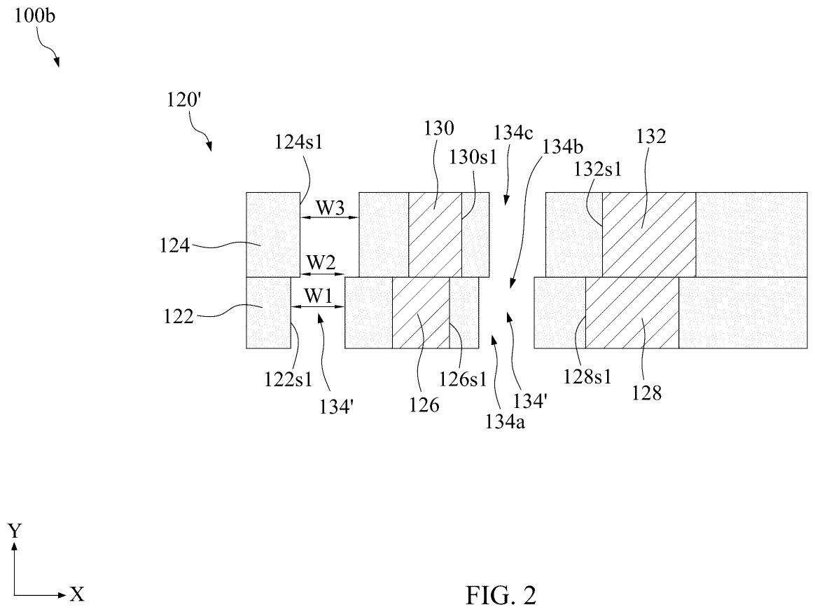

FIG. 2 is a cross-sectional view of a semiconductor device structure 1b, in accordance with some embodiments of the present disclosure.

The semiconductor device structure 1b may include a hybrid bond structure 120′. In some embodiments, the first dielectric layer 122 is misaligned with the second dielectric layer 124.

The first dielectric layer 122 may have a surface 124s1 (or a lateral surface). The second dielectric layer 124 may have a surface 124s1 (or a lateral surface). In some embodiments, the surface 124s1 of the first dielectric layer 122 may be misaligned or noncoplanar with the surface 124s1 of the second dielectric layer 124.

In some embodiments, the conductive layer 126 is misaligned with the conductive layer 130. The conductive layer 126 may have a surface 126s1 (or a lateral surface). The conductive layer 130 may have a conductive layer 130sl (or a lateral surface). In some embodiments, the surface 126s1 of the conductive layer 126 may be misaligned or noncoplanar with the conductive layer 130sl of the hybrid bond structure 120. In some embodiments, the conductive layer 128 is misaligned with the conductive layer 132. The conductive layer 128 may have a surface 128s1 (or a lateral surface). The conductive layer 132 may have a conductive layer 132s1 (or a lateral surface). In some embodiments, the surface 128s1 of the conductive layer 128 may be misaligned or noncoplanar with the conductive layer 132s1 of the conductive layer 132.

The hybrid bond structure 120′ may include an air gap 134′ defined by the misaligned dielectric structure. In some embodiments, the air gap 134′ may include a first terminal portion 134a, a neck portion 134b, and a second terminal portion 134c. The first terminal portion 134a may abut the first substrate 102. The second terminal portion 134c may abut the second substrate 140. The neck portion 134b may be located between the first terminal portion 134a and second terminal portion 134c. The neck portion 134b may be in communication with the first terminal portion 134a. The neck portion 134b may be in communication with the second terminal portion 134c. In some embodiments, the first terminal portion 134a may be misaligned with the second terminal portion 134c. The first terminal portion 134a may have a length (or a width or a diameter) W1. The neck portion 134b may have a length (or a width or a diameter) W2. The second terminal portion 134c may have a length (or a width or a diameter) W3. In some embodiments, the length W1 may be greater than the length W2. In some embodiments, the length W3 may be greater than the length W2. In some embodiments, the length W1 may be substantially equal to the length W3.

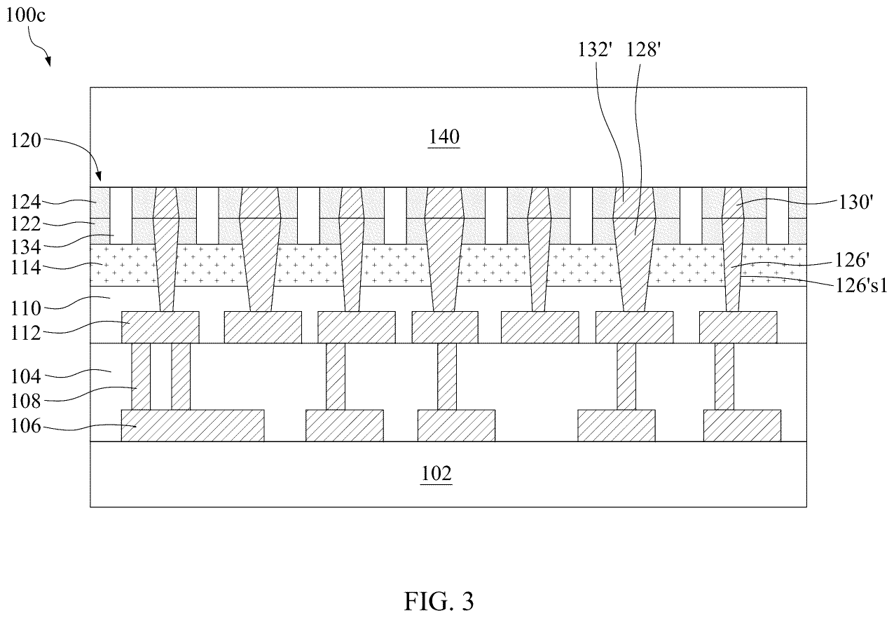

FIG. 3 is a cross-sectional view of a semiconductor device structure 100c, in accordance with some embodiments of the present disclosure. The semiconductor device structure 100c may be similar to the semiconductor device structure 100a, and the differences between them are described as follows.

The semiconductor device structure 100c may include conductive layers 126′, 128′, 130′ and 132′. In some embodiments, the conductive layer 126′ may be continuously tapered toward the first substrate 102. The conductive layer 126′ may have a surface 126′s1. The surface 126′s1 may be continuously extend and contact the first dielectric layer 122, the passivation layer 114, and the interlayer dielectric 110. In some embodiments, the conductive layer 128′ may be continuously tapered toward the first substrate 102. In some embodiments, the conductive layer 130′ may be continuously tapered toward the second substrate 140. In some embodiments, the conductive layer 132′ may be continuously tapered toward the second substrate 140.

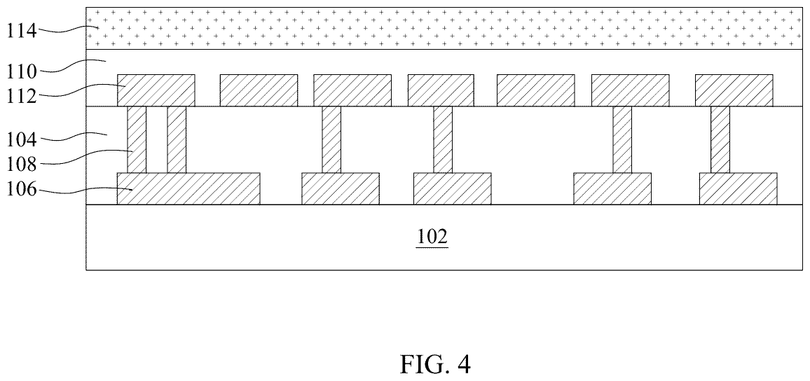

FIG. 4 to FIG. 16 illustrates various stages of an exemplary method for manufacturing a semiconductor device structure according to some embodiments of the present disclosure.

Referring to FIG. 4, a first substrate 102 may be provided. The conductive line 106 may be formed on the first substrate 102. The conductive line 106 may be formed by physical vapor deposition (PVD), chemical vapor deposition (CVD), atomic layer deposition (ALD), low-pressure chemical vapor deposition (LPCVD), or other suitable processes.

The interlayer dielectric 104 may be formed on the first substrate 102 and cover the conductive line 106. The interlayer dielectric 104 may be formed by chemical vapor deposition, physical vapor deposition, atomic layer deposition, low-pressure chemical vapor deposition, or other suitable processes.

The conductive via 108 and conductive line 112 may be formed on the conductive line 106. In some embodiments, an etching technique may be performed to define openings of the interlayer dielectric 104. A conductive material(s) may be formed to fill the openings of the interlayer dielectric 104 and cover the interlayer dielectric 104. The conductive material(s) may be formed by physical vapor deposition, chemical vapor deposition, atomic layer deposition, low-pressure chemical vapor deposition, or other suitable processes. A patterning technique may be performed to pattern the conductive material(s), which thereby produce the conductive via 108 and the conductive line 112. The patterning technique may include a photolithography technique(s) and an etching technique(s).

The interlayer dielectric 110 may be formed on the interlayer dielectric 104 and cover the conductive line 112. The interlayer dielectric 110 may be formed by chemical vapor deposition, physical vapor deposition, atomic layer deposition, low-pressure chemical vapor deposition, or other suitable processes.

In some embodiments, the passivation layer 114 may be formed on the interlayer dielectric 110. The passivation layer 114 may be formed by chemical vapor deposition, physical vapor deposition, atomic layer deposition, low-pressure chemical vapor deposition, or other suitable processes.

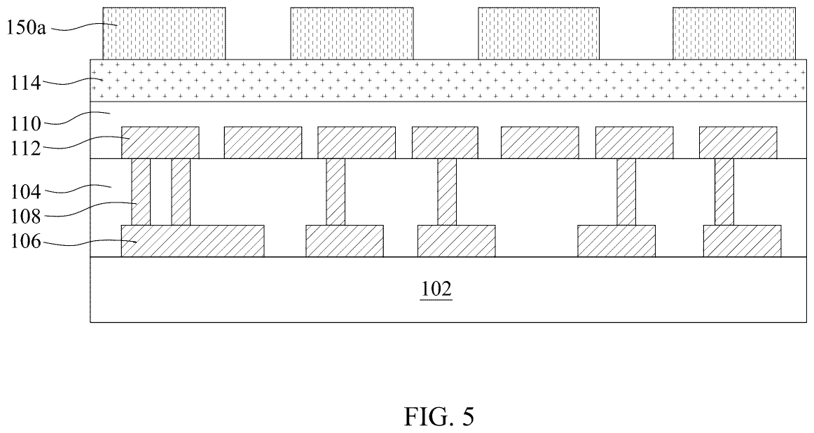

Referring to FIG. 5, a photosensitive layer 150a may be formed on the passivation layer 114. The photosensitive layer 150a may include a positive photoresist or a negative photoresist.

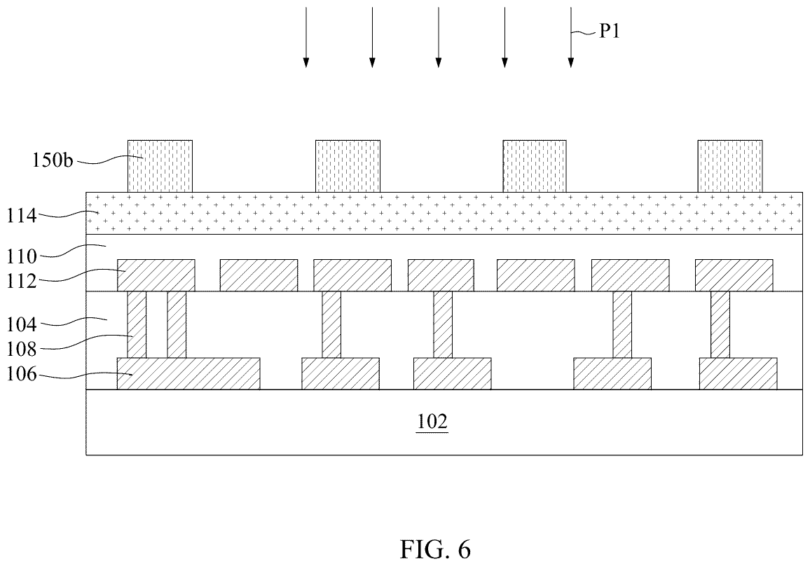

Referring to FIG. 6, an etching technique P1 may be performed to remove a portion of the photosensitive layer 150a, which thereby define a photosensitive layer 150b. In some embodiments, the etching technique P1 may include a dry etching technique. In some embodiments, an oxygen plasma may be used to remove a portion of the photosensitive layer 150a. The dimension (e.g., width or surface area) of the photosensitive layer 150b may be less than that of the photosensitive layer 150a.

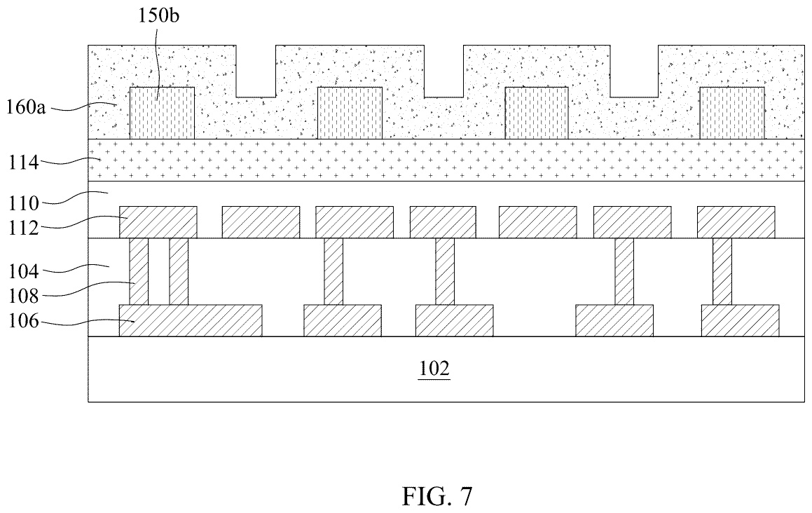

Referring to FIG. 7, a sacrificed layer 160a may be formed on the passivation layer 114. The sacrificed layer 160a may cover the photosensitive layer 150a. In some embodiments, the sacrificed layer 160a may include silicon nitride, silicon oxynitride, silicon oxide, hafnium oxide, aluminum oxide, titanium oxide, or other suitable materials. In some embodiments, the material of the sacrificed layer 160a may be different from that of the passivation layer 114. In some embodiments, the material of the sacrificed layer 160a may be different from that of the interlayer dielectric 110. For example, the sacrificed layer 160a may include nitride, while the passivation layer 114 may include oxide. The sacrificed layer 160a may be formed by chemical vapor deposition, physical vapor deposition, atomic layer deposition, low-pressure chemical vapor deposition, or other suitable processes.

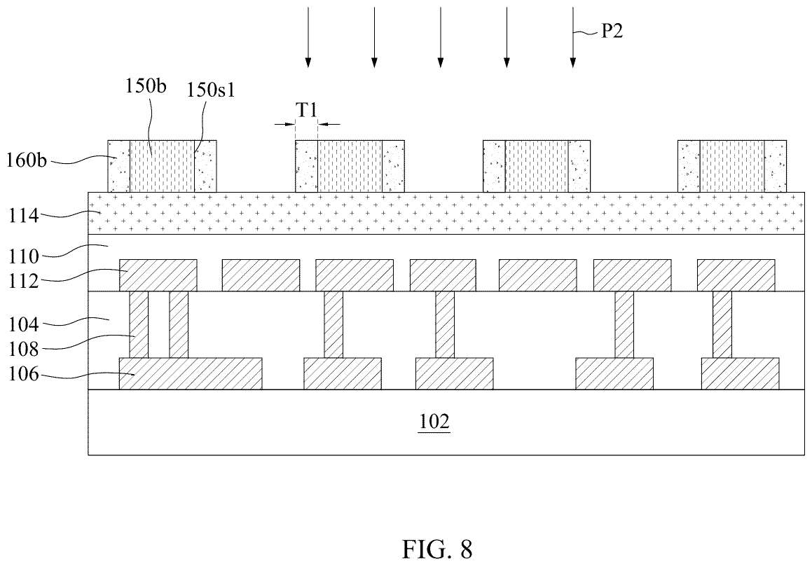

Referring to FIG. 8, an etching technique P2 may be performed. In some embodiments, a portion of the sacrificed layer 160a may be removed, which thereby defines a sacrificed layer 160b. In some embodiments, the sacrificed layer 160b may be disposed on a surface 150s1 of the photosensitive layer 150b. In some embodiments, the sacrificed layer 160b may be configured to define the location or position of an air gap, which will be subsequently formed. The dimension T1 of the sacrificed layer 160b may determine a dimension of the air gap. The dimension T1 of the sacrificed layer 160b may determine dimensions of conductive layers subsequently formed.

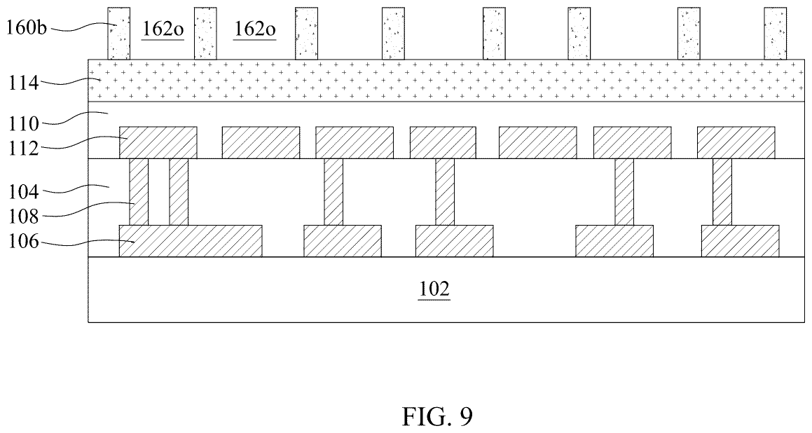

Referring to FIG. 9, the photosensitive layer 150b may be removed, which thereby defines opening 1620 (or aperture) exposing the passivation layer 114.

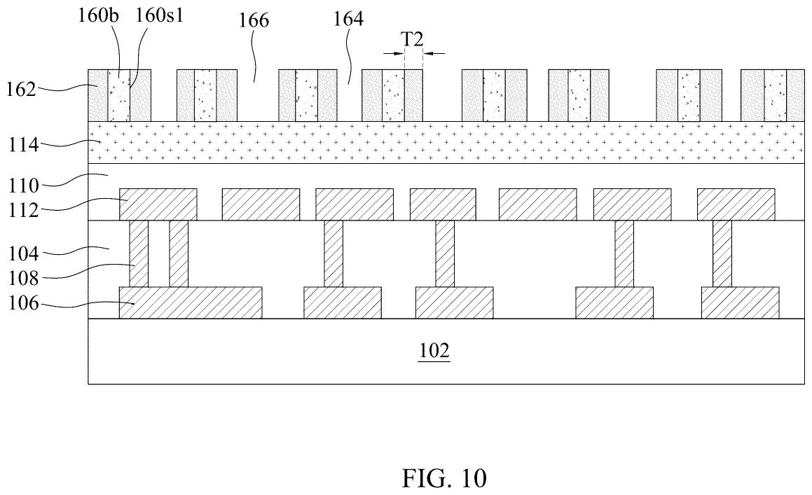

Referring to FIG. 10, a 162 may be formed. The 162 may be formed on a sacrificed layer 160sl (or a lateral surface) of the sacrificed layer 160b. As a result, openings 164 and 166 (or apertures) are defined and expose the passivation layer 114. The openings 164 and 166 may have different dimensions (e.g., length, width, diameter, or surface area). In some embodiments, the thickness T2 of the 162 may be configured to determine the dimension of the conductive layer (or conductive structure) subsequently formed. The 162 may be formed by chemical vapor deposition, physical vapor deposition, atomic layer deposition, low-pressure chemical vapor deposition, or other suitable processes. In some embodiments, the material of the 162 may be different from that of the sacrificed layer 160b. In some embodiments, the material of the 162 may be different from that of the passivation layer 114. In some embodiments, the 162 may include silicon carbonitride, silicon carbide, silicon oxide, silicon nitride, silicon oxynitride, or other suitable materials.

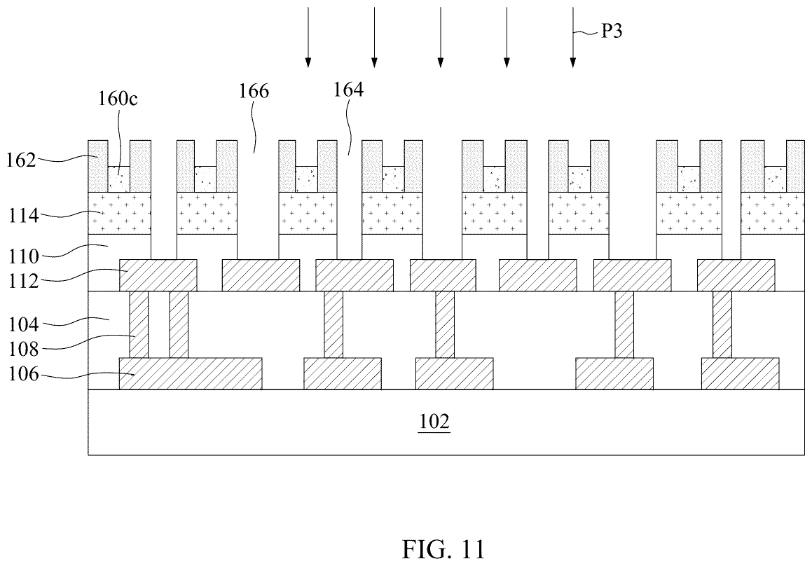

Referring to FIG. 11, an etching technique P3 may be performed. A portion of the sacrificed layer 160b may be removed, which thereby defines a sacrificed layer 160c with a thickness less than that that of the 162. A portion of the passivation layer 114 exposed by the openings 164 and 166 is removed. A portion of the interlayer dielectric 110 exposed by the openings 164 and 166 is removed. The conductive line 112 may be exposed.

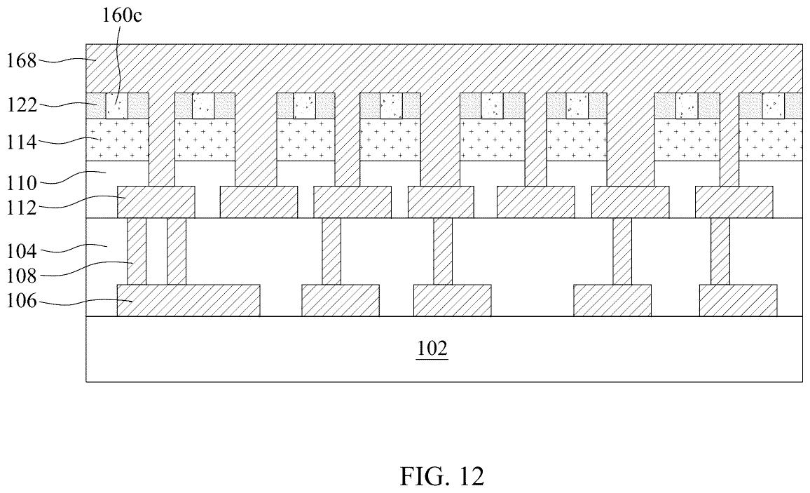

Referring to FIG. 12, a polishing technique (e.g., chemical mechanical polishing (CMP)) may be performed to remove a portion of the 162, which thereby defines a first dielectric layer 122. A conductive material 168 may be formed to fill the openings 164 and 166. The conductive material 168 may cover the first dielectric layer 122 and the sacrificed layer 160c. The conductive material 168 may be formed by physical vapor deposition, chemical vapor deposition, atomic layer deposition, low-pressure chemical vapor deposition, or other suitable processes.

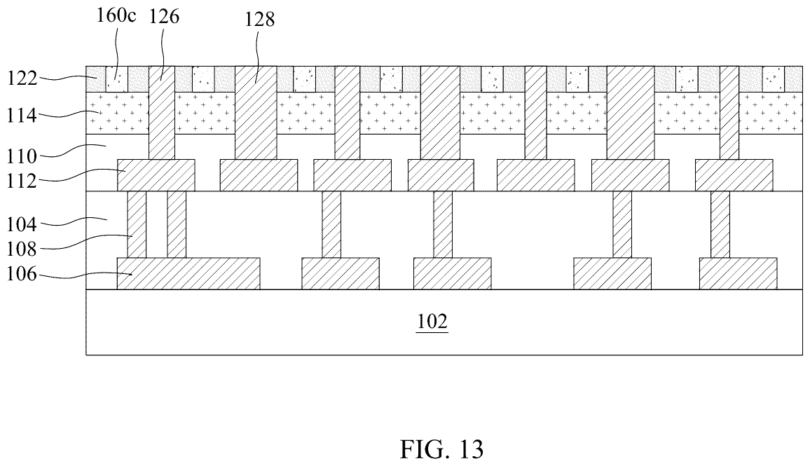

Referring to FIG. 13, a polishing technique (e.g., chemical mechanical polishing (CMP)) may be performed to remove a portion of the conductive material 168, which thereby defines a conductive layer 126 and a conductive layer 128 with different dimensions. The first dielectric layer 122 and the sacrificed layer 160c may be exposed.

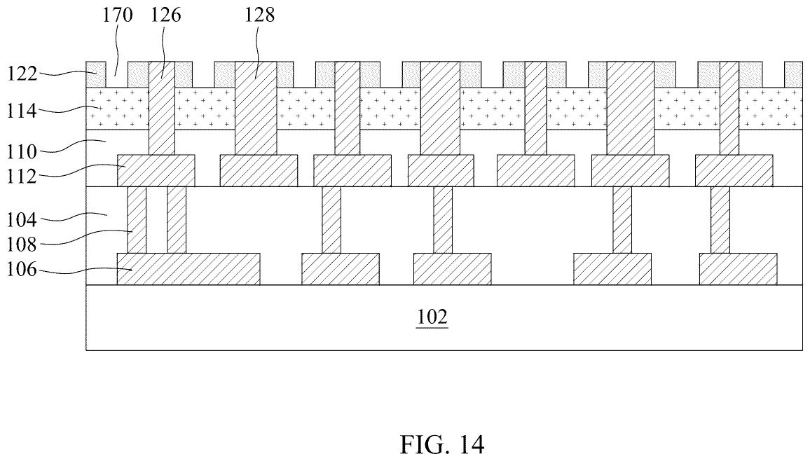

Referring to FIG. 14, the sacrificed layer 160c may be removed, which thereby defines a first opening 170 (or first aperture) surrounded by the first dielectric layer 122.

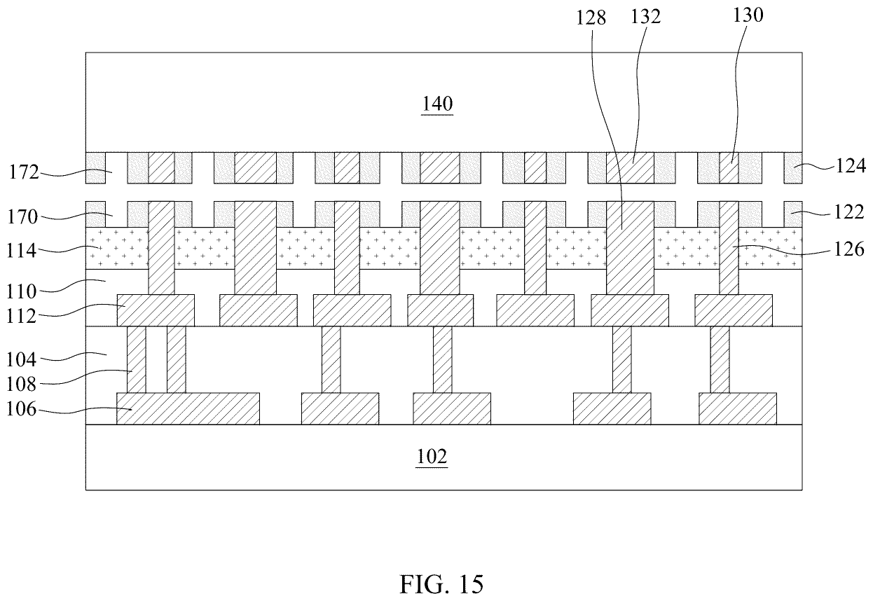

Referring to FIG. 15, a second substrate 140 may be provided. A second dielectric layer 124 may be formed on the second substrate 140. A conductive layer 130 and a conductive layer 132, with different dimensions, may be formed on the second substrate 140. A second opening 172 (or second aperture) may be surrounded by the second dielectric layer 124.

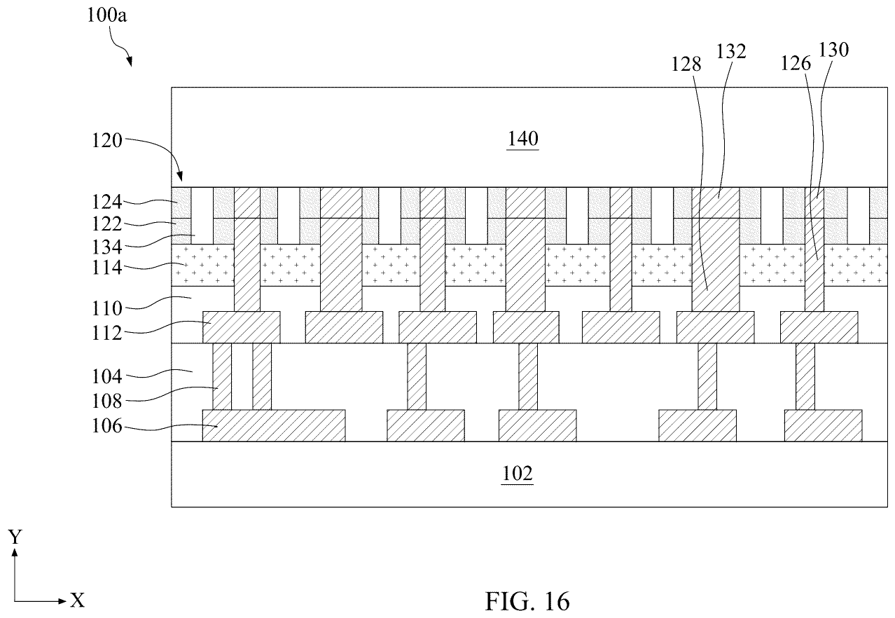

Referring to FIG. 16, a hybrid bond technique may be performed to bonding the first substrate 102 and the second substrate 140. The first dielectric layer 122 may be bonded to the second dielectric layer 124. The conductive layer 126 may be bonded to the conductive layer 130. The conductive layer 128 may be bonded to the conductive layer 132. The first opening 170 and second opening 172 may be collaboratively define an air gap 134. As a result, a semiconductor device structure (e.g., the semiconductor device structure as shown in FIG. 1) may be produced.

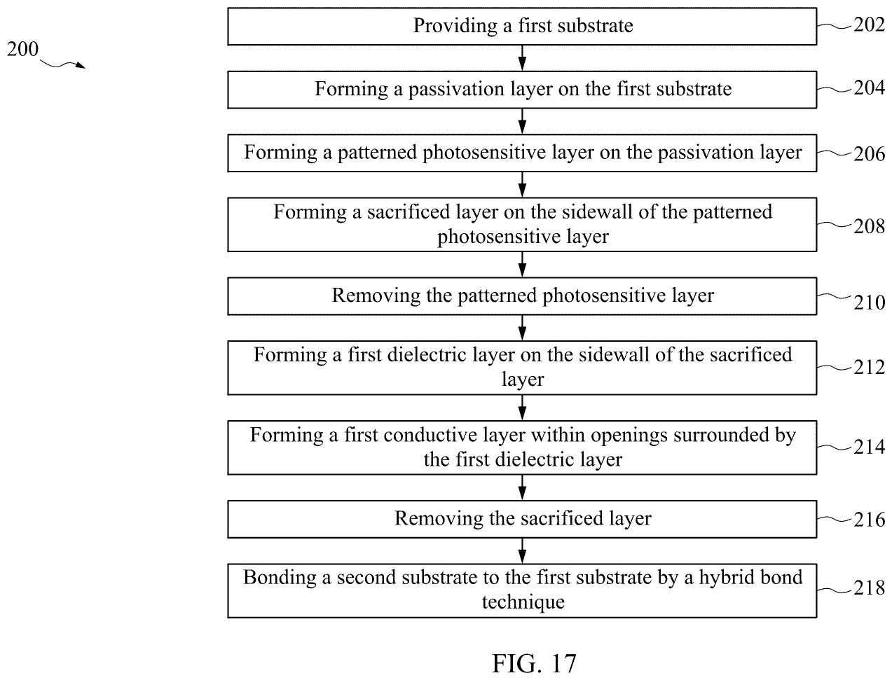

FIG. 17 is a flowchart illustrating a method 200 of manufacturing a semiconductor device structure, in accordance with some embodiments of the present disclosure.

The method 200 begins with operation 202 in which a first substrate is provided.

The method 200 continues with operation 204 in which a passivation layer is formed on the first substrate. FIG. 4 illustrates a stage corresponding to operation 202 and 204.

The method 200 continues with operation 206 in which a patterned photosensitive layer is formed on the passivation layer. FIG. 5 illustrates a stage corresponding to operation 206.

The method 200 continues with operation 208 in which a sacrificed layer is formed on the sidewall of the patterned photosensitive layer. In some embodiments, the patterned photosensitive layer may be further etched. In some embodiments, the sacrificed layer may be formed on the upper surface and the sidewall of the patterned photosensitive layer. In some embodiments, a portion of the sacrificed layer may be removed by an etching technique so that the sacrificed layer remains on the sidewall of the patterned photosensitive layer. FIG. 5 to FIG. 8 illustrate a stage corresponding to operation 208.

The method 200 continues with operation 210 in which the patterned photosensitive layer is removed. FIG. 9 illustrates a stage corresponding to operation 210.

The method 200 continues with operation 212 in which a first dielectric layer is formed on the sidewall of the sacrificed layer. FIG. 10 illustrates a stage corresponding to operation 212.

The method 200 continues with operation 214 in which a first conductive layer is formed within openings surrounded by the first dielectric layer. FIG. 11 to FIG. 13 illustrate a stage corresponding to operation 214. In some embodiments, a portion of the sacrificed layer may be removed. In some embodiments, the first dielectric layer may be polished so that the first dielectric layer is level with the sacrificed layer. In some embodiments, a conductive material is deposited to cover the upper surfaces of the sacrificed layer and the first dielectric layer. In some embodiments, a polish technique may be performed to planarize the conductive material so that the upper surface of the conductive layer is level with those of the sacrificed layer and the first dielectric layer.

The method 200 continues with operation 216 in which the sacrificed layer is removed to define a first opening. FIG. 14 illustrates a stage corresponding to operation 216.

The method 200 continues with operation 218 in which a second substrate is bonded to the first substrate. A second dielectric layer is formed on the second substrate. A second conductive layer is formed on the second substrate. A second opening is defined and surrounded by the second dielectric layer. A hybrid bond technique may be performed to bond the first substrate and the second substrate. An air gap may be formed aligning the first opening and the second opening. FIG. 15 and FIG. 16 illustrate a stage corresponding to operation 210.

One aspect of the present disclosure provides a semiconductor device structure. The semiconductor device structure includes a first substrate, a second substrate, and a hybrid bond structure. The second substrate is bonded to the first substrate by the hybrid bond structure. The hybrid bond structure includes a dielectric structure, a conductive structure. The dielectric structure defines an air gap therein.

Another aspect of the present disclosure provides a semiconductor device structure. The semiconductor device structure includes a first substrate, a passivation layer, a conductive line, a dielectric structure, a first conductive layer, a second conductive layer, and an air gap. The passivation layer is disposed over the first substrate. The conductive line is disposed within the passivation layer. The dielectric structure is disposed over the passivation layer. The first conductive layer is electrically connected to the conductive line. The second conductive layer is disposed over the first conductive layer and electrically connected to the conductive line through the first conductive layer. The air gap is disposed within the dielectric structure. The air gap laterally overlaps the first conductive layer.

Another aspect of the present disclosure provides a method for manufacturing a semiconductor device structure. The method includes: providing a first substrate; forming a first dielectric layer over the first substrate, wherein the first dielectric layer defines a first opening and a second opening; forming a first conductive layer within the first opening; providing a second substrate, wherein a second dielectric layer is formed on the second substrate, a second conductive layer penetrates the second dielectric layer, and the second dielectric layer defines a third opening; and bonding the first dielectric layer to the second dielectric layer and bonding the first conductive layer and the second conductive layer to define a hybrid bond structure with an air gap formed by the second opening and the third opening.

The embodiments of the present disclosure provide a semiconductor device structure and method of manufacturing the same. The semiconductor device structure may include a first substrate and a second substrate bonded to the first substrate through a hybrid bond technique. In this embodiment, the hybrid bond structure includes an air gap so that the parasitic capacitance between abutting conductive structures within the hybrid bond structure can be reduced.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A semiconductor device structure, comprising:
a first substrate;
a second substrate attached to the first substrate by a hybrid bond structure, wherein the hybrid bond structure comprises a dielectric structure and a conductive structure; and
a passivation layer disposed between the hybrid bond structure and the first substrate, wherein the first conductive layer penetrates the passivation layer;
wherein the dielectric structure defines an air gap;
wherein the air gap comprises a first terminal portion and a neck portion in communication with the first terminal portion, and an aperture of the first terminal portion is different from an aperture of the neck portion.

2. The semiconductor device structure of claim 1, wherein the air gap is spaced apart from the conductive structure by the dielectric structure.

3. The semiconductor device structure of claim 1, wherein the conductive structure comprises a first conductive layer and a second conductive layer bonded to the first conductive layer.

4. The semiconductor device structure of claim 1, wherein the first conductive layer is continuously tapered toward the first substrate.

5. The semiconductor device structure of claim 4, wherein the second conductive layer is tapered toward the second substrate.

6. The semiconductor device structure of claim 1, wherein a material of the passivation layer is different from a material of the, and the air gap further comprises a second terminal portion in communication with the neck portion.

7. The semiconductor device structure of claim 6, wherein the first terminal portion is partially misaligned with the second terminal portion.

8. The semiconductor device structure of claim 1, wherein the conductive structure comprises a first segment and a second segment, the first segment has a first dimension, and the second segment has a second dimension different from the first dimension.

9. The semiconductor device structure of claim 1, wherein the first substrate comprises a memory device.

10. A semiconductor device structure, comprising:
a first substrate;
a passivation layer disposed over the first substrate;
a conductive line between the passivation layer and the first substrate;
a dielectric structure disposed over the passivation layer;
a first conductive layer electrically connected to the conductive line; and
a second conductive layer disposed over the first conductive layer and electrically connected to the conductive line through the first conductive layer;
wherein the dielectric structure defines an air gap laterally overlapping the first conductive layer;
wherein the first conductive layer further penetrates the passivation layer;
wherein a vertical dimension of the first conductive layer is greater than a horizontal dimension of the first conductive layer;
wherein the first conductive layer is partially misaligned with the second conductive layer.

11. The semiconductor device structure of claim 10, wherein the air gap laterally overlaps the second conductive layer.

12. The semiconductor device structure of claim 11, wherein a sidewall of the first conductive layer continuously extends from the dielectric structure to the passivation layer.

13. The semiconductor device structure of claim 10, wherein the first conductive layer is tapered toward the first substrate.

14. The semiconductor device structure of claim 13, further comprising:
a second substrate disposed over the second conductive layer, wherein the second conductive layer is tapered toward the second substrate.

15. The semiconductor device structure of claim 14, wherein the second substrate comprises a semiconductor substrate.

16. The semiconductor device structure of claim 10, wherein a material of the passivation layer is different from a material of the dielectric structure.

17. The semiconductor device structure of claim 10, wherein the air gap comprises a first terminal portion abutting the passivation layer and a neck portion in communication with the first terminal portion, and an aperture of the first terminal portion is different from an aperture of the neck portion.

18. The semiconductor device structure of claim 17, wherein the air gap further comprises a second terminal portion in communication with the neck portion.
